(19) United States
(12) Patent Application Publication
(10) Pub. No.: US 2023/0317536 A1
(43) Pub. Date: Oct. 5, 2023

(54) GROOVED PACKAGE

(71) Applicant: Intel Corporation, Santa Clara, CA (US)

(72) Inventors: Georg SEIDEMANN, Landshut (DE); Bernd WAIDHAS, Pettendorf (DE); Thomas WAGNER, Regelsbach (DE); Stephan STOECKL, Schwandorf (DE)

(21) Appl. No.: 17/707,536

(22) Filed: Mar. 29, 2022

(51) Int. Cl. H01L 23/31; H01L 23/538; H01L 25/065; H01L 21/56

(52) U.S. Cl. CPC H01L 23/3107; H01L 23/5381; H01L 25/0655; H01L 21/56

(57) ABSTRACT

Embodiments herein relate to systems, apparatuses, techniques or processes related to packages that are fully or partially encapsulated in a mold material, with one or more grooves in the mold material to reduce failure in the package during operation. In embodiments, the grooves will allow greater flexibility within the body of the package as it experiences thermo-mechanical stress during operation and will reduce stresses that may be placed on internal components such as chips or bridges in the package, as well as stresses that may be placed on interconnects of the package that are coupled to a substrate. Other embodiments may be described and/or claimed.

### FIELD

Embodiments of the present disclosure generally relate to the field of package assemblies, and in particular package assemblies that include multiple dies within a mold material.

### BACKGROUND

Continued reduction in end product size of mobile electronic devices such as smart phones and ultrabooks is a driving force for the development of reduced size system in package components.

### BRIEF DESCRIPTION OF THE DRAWINGS

FIG. 1 illustrates a perspective view and a cross section side view of a legacy implementation of a package that includes multiple dies coupled with one or more bridges.

FIGS. 2A-2B illustrate examples of a perspective view and a cross section side view of a package with grooves in a molded portion of the package, and where the grooves are filled with a material, in accordance with various embodiments.

FIG. 3 illustrates a cross section side view and a top-down view of a package that includes multiple dies with grooves in a molded portion of the package, in accordance with various embodiments.

FIGS. 4A-4T illustrate stages in a manufacturing process for creating a package with grooves in a mold of the package, in accordance with various embodiments.

FIG. 5 illustrates top-down views of various patterns of grooves that may be made in a mold of a package, in accordance with various embodiments.

FIGS. 6A-6P illustrate various top-down views of patterns of grooves in mold of a package, in accordance with various embodiments.

FIG. 7 illustrates an example of a process for creating a package with grooves in a mold of the package, in accordance with various embodiments.

FIG. 8 schematically illustrates a computing device, in accordance with embodiments.

### DETAILED DESCRIPTION

Embodiments of the present disclosure may generally relate to systems, apparatus, and/or processes directed to packages that include multiple dies within the package, and in embodiments where those multiple dies are coupled with one or more bridges within the package. The package may be fully or partially encapsulated with a mold material, with one or more grooves in the mold material to reduce failure in the package during operation. In embodiments, the package may have any number or configuration of components. Embodiments may not be limited to grooves in the molded portion of a package, but may also include groves in a side of a substrate, a dielectric layer, a mold layer, and/or any other component or material in a package.

In embodiments, the grooves in the mold material of the package may also be referred to as slots or cuts. In embodiments, the grooves facilitate greater flexibility within the body of the package as it experiences thermo-mechanical stress during operation. The greater flexibility of the package will reduce stresses that may be placed on internal components of the package, such as but not limited to, chips or bridges, as well as stresses that may be placed on interconnects of the package that are coupled to a substrate. These stresses would otherwise not be mitigated in a legacy rigid body package.

Legacy packages integrating more functions within the package to, in part, achieve more affordable costs. As a result, previous monolithic die integration approaches are now moving towards a disaggregation approach, where smaller dies are connected with bridges within a package. This trend, however, is leading to packages that have a greater footprint, which creates more challenges during production and assembly of these larger packages. For example, the challenges of these legacy packages may be due to thermal-mechanical stress during the lifetime of the package operation. In addition, warpage of the package may be caused by using multiple materials, for example silicon dies, dielectric, and substrates, that have different coefficients of thermal expansion (CTE) that introduce different stresses during operation.

These legacy packages, in comparison to a monolithic system-on-a-chip, are built as chiplets using multiple dies, or may be built with fan-out technology, and often in combination with a silicon interposer, a redistribution layer (RDL) interposer, and/or substrates. Due to the rigidness of buildups of these legacy packages, they are highly sensitive to warpage at a later assembly process. In addition, they are also at risk of cracking during the assembly process, as well as during operation. Legacy approaches to mitigate this warpage include using thicker dies, larger pads or solder bump dimensions on interconnects, and/or using special materials within the package, such as a special molding compounds. As a result, with these legacy packages, failures on interfaces within and on the outside of the package will occur. Cracks within the package and through different layers may be introduced, as well as line damage within the package.

Legacy package manufacturing techniques may include using expensive non-reusable carrier systems to reduce warpage. In addition, extensive development time is being spent on designing optimized stack up of materials within the package to improve a total CTE in order to avoid built-in stress and pre-tensions within the package. These legacy optimizations result in higher package costs and/or higher time to market. These limitations in legacy implementations particularly regarding warpage within buildups prevent an increase in the size of packages. These limitations also restrict using the package in harsher environmental conditions that may exacerbate strain or stress within the package.

In embodiments described herein, the rigidness and stability of a package is modified so that the package can experience a greater degree of flexibility and thus can be bent and internal package stress can be reduced. In embodiments, this flexibility may be accomplished by grooving, or slotting, a side of the package using mechanical sawing techniques and/or laser grooving techniques to reduce the rigidness of the package and to subsequently reduce the warpage of the package, for example during board assembly.

In embodiments, the grooves may take a number of different shapes and dimensions. In non-limiting embodiments, the grooves may be formed as a continuous line, as dashed and/or dotted lines, or as a sequence of dot shapes when viewed top-down. In addition, the width and/or depth of the grooves may be varied depending upon the architecture of the package or the architecture of various components within the package.

In embodiments, during the mechanical sawing phase, the dies and/or bridges within the package may be protected with additional metal layers within the package. In embodiments, the grooves may be filled with various types of material to create additional electrical contacts and/or electrical contact areas, for example to provide a power supply to components within the package. Other material may be used to provide electromagnetic interference (EMI) shielding for components within the package, or to provide thermal isolation between dies or other components within the package.

In embodiments, because the overall package structure is more flexible, the built-in stress and the risk of package cracks is reduced. In addition, due to the resulting lower warpage of the package, stress on interconnects, such as the stress on solder balls and the risk of solder ball fatigue, is reduced. Embodiments will increase the robustness and longevity of the package.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

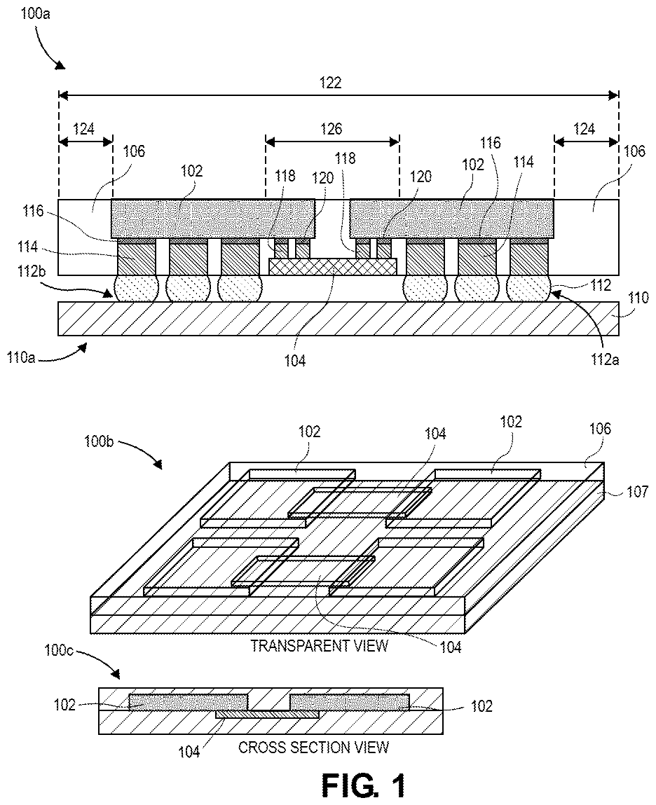

FIG. 1 illustrates a perspective view and a cross section side view of a legacy implementation of a package that includes multiple dies coupled with a bridge. Legacy package 100a is a cross section side view that includes a plurality of dies 102 that are electrically and physically coupled with a bridge 104. In embodiments, the plurality of dies 102 may include silicon dies. In implementations, the bridge 104 may be an embedded multi-die interconnect bridge (EMIB)™ or some other bridging technology. The plurality of dies 102 and the bridge 104 may be at least partially surrounded in a mold material 106. In implementations, the mold material may include filler material and an epoxy.

Legacy package 100a may be coupled with the substrate 110 via interconnect 112. In implementations, the interconnect 112 may be a solder interconnect. The interconnect 112 may be electrically and physically coupled with the dies 102 by way of copper pillars 114, that may connect with the dies 102 using a pad 116. In implementations, the bridge 104 may be electrically and/or physically coupled with the dies 102 by copper pillars 118 that may connect with the dies 102 using a pad 120.

Note that with legacy package 100a, an overall width of the package 122 may be quite large, and areas of the package 124 may extend beyond the interconnect 112. In addition, internal areas of the package 126 may extend between gaps in the interconnect 112. During manufacturing and/or operation of the legacy package 100a, different CTEs of different components of the legacy package 100a, for example the dies 102, the bridge 104, and/or the copper pillars 114, 118, may cause internal stresses within the package. In addition, stresses and/or deformation that occur within the substrate 110 may put added stress on the interconnect 112, and may cause stress fracture decoupling, or solder fatigue, at locations 112a, 112b. This may occur, for example, if the mold material 106 is too rigid and is not able to partially deform with any deformation 110a of the substrate 110.

Legacy package 100b is a perspective view of a package that may be similar to legacy package 100a, with a plurality of dies 102, which may be referred to as chiplets, coupled with bridges 104 that are within a mold material 106 on a substrate 107. In embodiments, the plurality of dies 102 may be part of a multi-die fanout stack up (not shown). Note that the mold material 106 in legacy package 100b is shown as transparent. In some implementations, substrate 107 may be similar to substrate 110 of legacy package 100a. Legacy package 100c is a cross section side view of a portion of legacy package 100b. Although legacy package 100b shows just four dies 102, it should be appreciated that other legacy packages may contain substantially more dies and have a substantially larger footprint. As the footprint of such legacy packages grow, the issue of strain and stress within the legacy package, as well as with interconnects such as interconnects 112 that couple the legacy package to a substrate 110, will greatly increase.

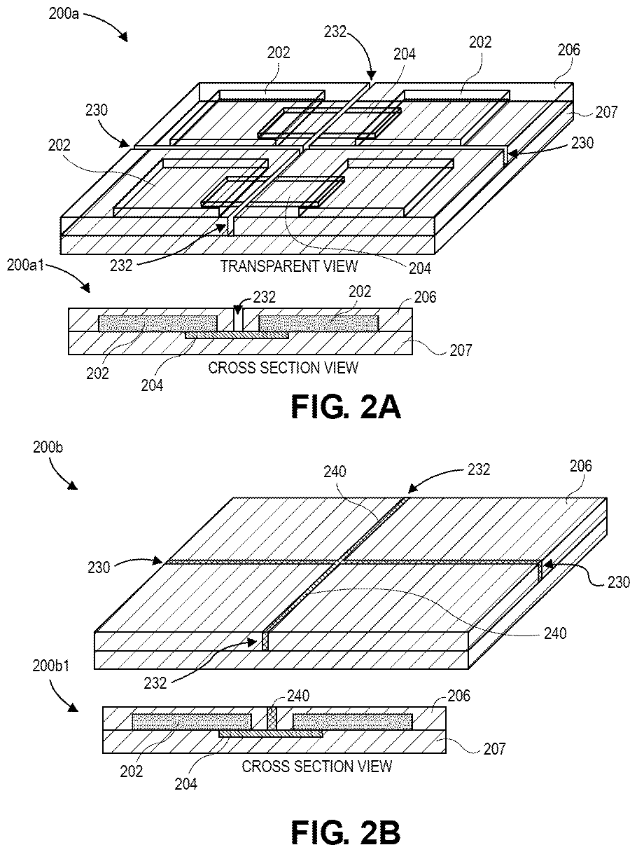

FIGS. 2A-2B illustrate examples of a perspective view and a cross section side view of a package with grooves in a molded portion of the package, and where the grooves are filled with a material, in accordance with various embodiments. FIG. 2A shows package 200a, which may be similar to package 100b of FIG. 1, includes a plurality of dies 202 that are coupled with a plurality of bridges 204. In embodiments, the dies 202 and the bridges 204 may be encapsulated within a mold material 206. In embodiments, the dies 202, bridges 204, and mold material 206 may be on a substrate 207.

In embodiments, grooves 230, 232 may be formed in the mold material 206. In embodiments, the grooves 230, 232 may be referred to as slots. In embodiments, the grooves 230, 232 may be of an arbitrary width and may have an arbitrary or variable depth. In addition, as shown, the groove 232 of package 200a1, a cross-section side view of package 200a, has a rectangular shape. However, in other embodiments, the groove 232 may another shape, such as trapezoidal, curved, or any other shape.

As shown, the grooves 230, 232 are substantially perpendicular to each other and are placed between one or more of the dies 202. In addition, groove 232 is shown as extending down toward and proximate to a surface of the bridge 204. In other embodiments, not shown, the grooves 230, 232 may be placed at other locations within the mold material 206, and do not have to be perpendicular to each other. In embodiments, the grooves 230, 232 do not need to be in a straight line, nor do they need to run continuously from edge of the mold material 206 to another edge of the mold material 206.

FIG. 2B shows package 200b, which may be similar to package 200a of FIG. 2A, where the grooves 230, 232 have been filled with a filler 240. Note that in FIG. 2B, mold material 206 is shown as nontransparent. In embodiments, the filler 240 may include, for example but not limited to, silicon. In embodiments, the filler 240 may be filled with electromagnetic interference (EMI) blocking material, that may be used to reduce EMI received by or emanating from one of the dies 202. In other embodiments, the filler 240 may include metal or other conductive substance, such that the filler 240 may serve as an electrical bus. In these embodiments, the filler 240 may come into electrical contact with a component of the package 200a, for example a bridge 204, and provide electrical power for the bridge 204. In other embodiments, and electrically conductive filler 240 may be used to route power or signals between electrical components such as dies 202 and bridges 204 of the package 200a. Package 200b1 is a cross section side view of a portion of package 200b.

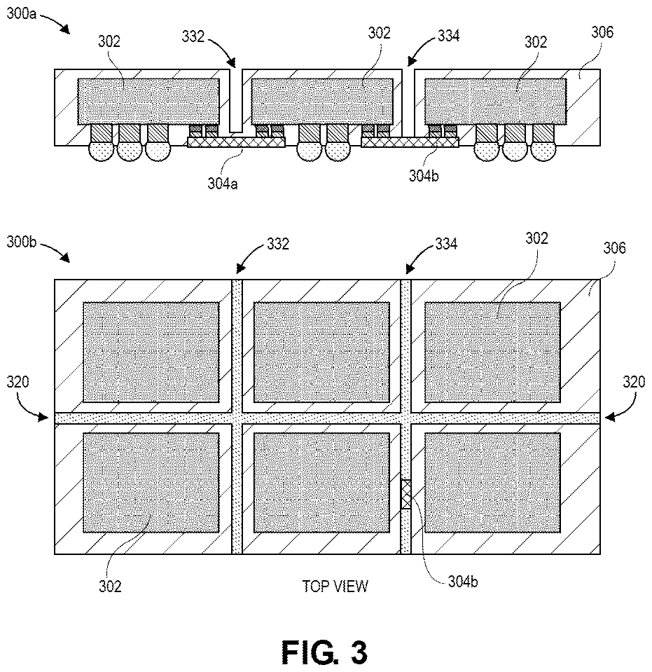

FIG. 3 illustrates a cross section side view and a top-down view of a package that includes multiple dies with grooves in a mold material of the package, in accordance with various embodiments. Package 300a, which may be similar to package 100a of FIG. 1, shows a cross section side view of a plurality of dies 302, with some of the dies 302 coupled by a first bridge 304a, and some of the dies 302 coupled by a second bridge 304b. In embodiments, the dies 302 may be similar to dies 202, and bridges 304a, 304b may be similar to bridges 204 of FIGS. 2A-2B. The dies 302 and the bridges 304a, 304b are surrounded by a mold material 306, which may be similar to mold material 206 of FIGS. 2A-2B.

In embodiments, grooves 332, 334 may be formed into the mold material 306 between the dies 302. As shown in package 300b, a top-down view of package 300a, a groove 320 is formed that is substantially perpendicular to grooves 332, 334. In embodiments, the grooves 320, 332, 334 may be sawn, or may be laser drilled. In this embodiment, groove 332 is sawn from a top edge of the mold material 306 down to a location proximate to the bridge 304a. Groove 334 is sawn from a top edge of the mold material 306 down to a surface of the bridge 304b and exposing the surface of the bridge 304b. In some embodiments, groove 334 may extend partially into the bridge 304b. In subsequent steps, the groove 334 may be filled with an electrically conductive material (not shown) that electrically couples with the bridge 304b. In embodiments the electrical coupling may provide power to the bridge 304b.

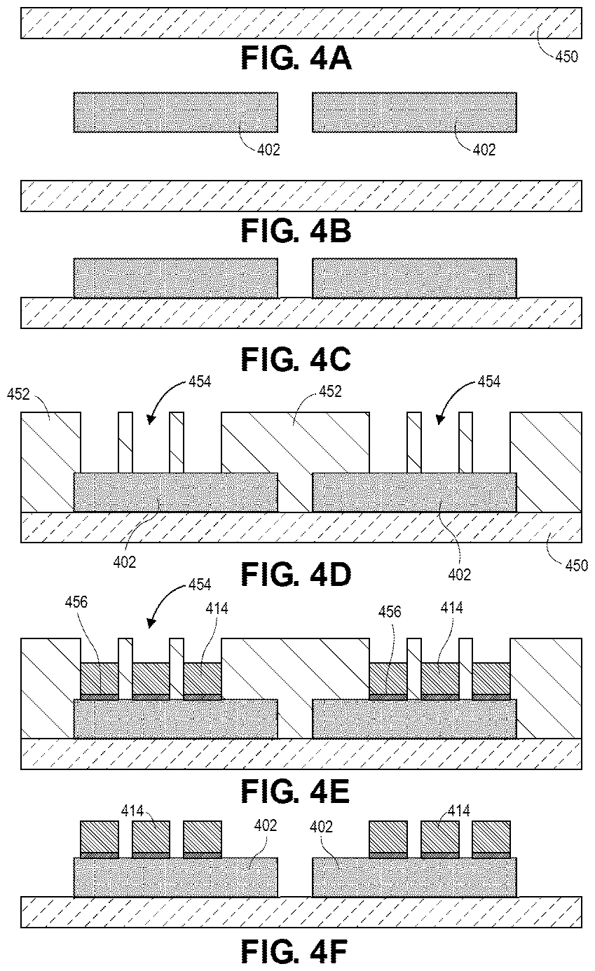

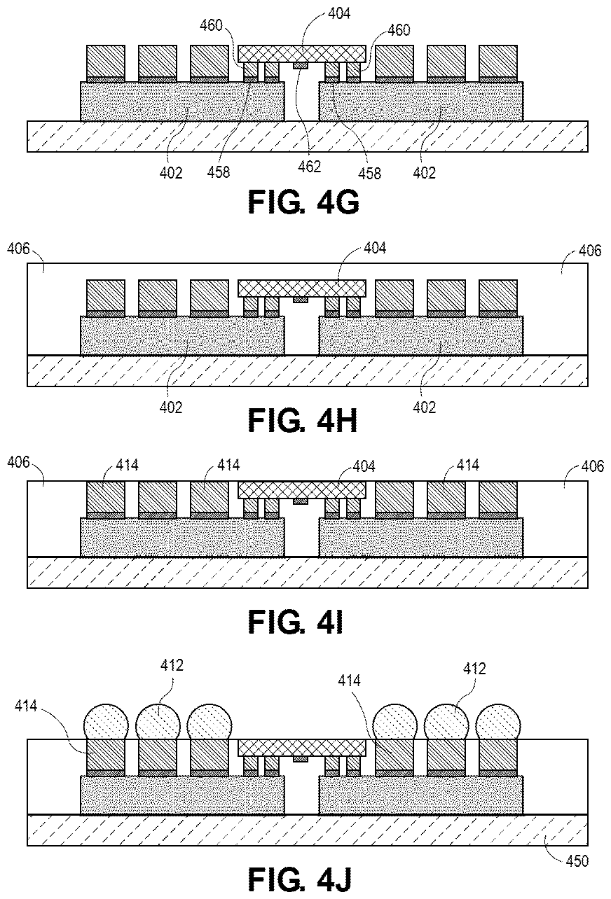

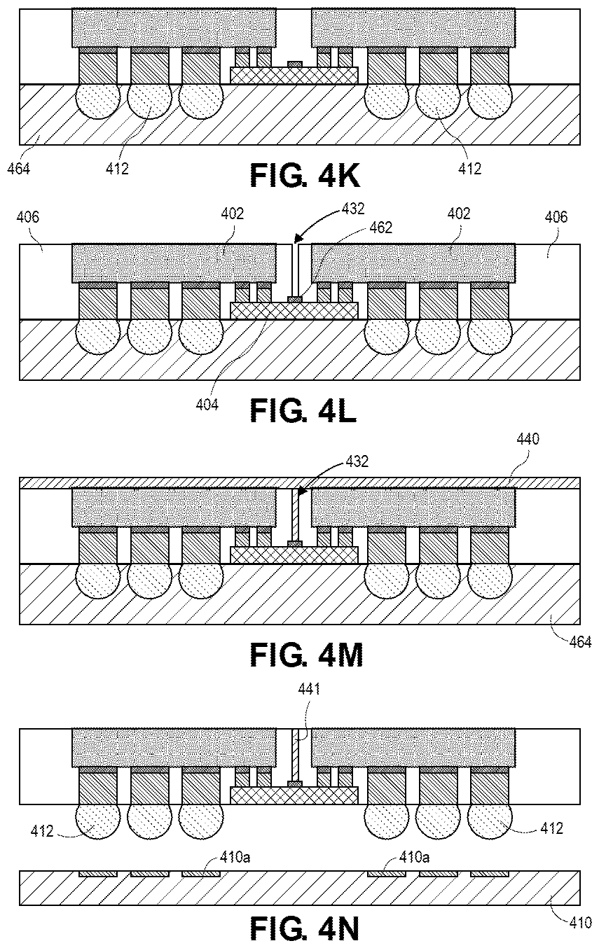

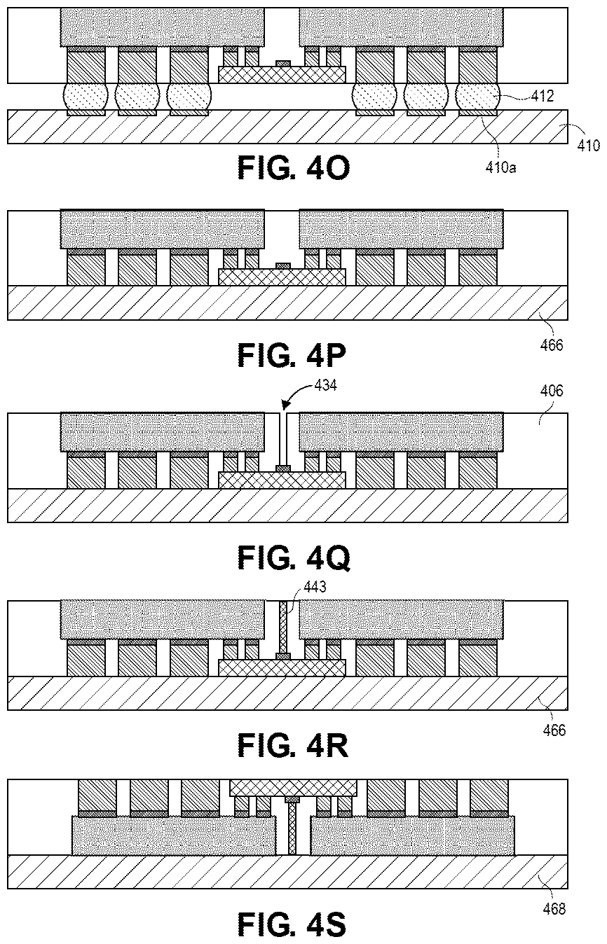

FIGS. 4A-4T illustrate stages in a manufacturing process for creating a package with grooves in a mold material of the package, in accordance with various embodiments. FIG. 4A shows a cross section side view of a stage in the manufacturing process where a carrier 450 is provided. In embodiments, the carrier may be a glass, a silicon, a metal, and/or a steel carrier.

FIG. 4B shows a cross section side view of a stage in the manufacturing process where silicon dies 402, which may be similar to silicon dies 302 of FIG. 3, are provided. FIG. 4C shows a cross section side view of the stage in the manufacturing process, where the dies 402 are placed on the carrier 450.

FIG. 4D shows a cross section side view of a stage in the manufacturing process where a plating resist 452 is placed on the dies 402 and the carrier 450. The plating resist 452 is then patterned and developed to form cavities 454 that exposed portions of surfaces of the dies 402.

FIG. 4E shows a cross section side view of a stage in the manufacturing process where a contact metal 456 is placed within cavities 454, for example by plating. In embodiments, a seed layer (not shown) may be used. A copper pillar 414, which may be similar to copper pillar 114 of FIG. 1, is placed on the contact metal 456, for example by copper plating.

FIG. 4F shows a cross section side view of a stage in the manufacturing process where the plating resist 452 of FIG. 4D is removed, leaving the copper pillar 414 and dies 402 exposed. In embodiments, the seed layer (not shown) from FIG. 4E may be removed prior to plating resist 452 removal.

FIG. 4G shows a cross section side view of a stage in the manufacturing process where contact metals 458 and copper pillars 460 are placed on the dies 402. A bridge 404, which may be similar to bridge 304a or bridge 304b of FIG. 3, may be placed on the copper pillars 460. In embodiments, the bridge 404 is electrically coupled with the dies 402. In embodiments, the bridge may be a silicon bridge, or a redistribution layer (RDL) bridge.

Note that in embodiments, a protector 462 may be coupled with a side of the bridge 404. The protector 462 may be subsequently used to protect the bridge 404 from damage when grooves, for example grooves 320, 332, 334 of FIG. 3, are made proximate to the bridge 404. In embodiments, the protector 462 may be an electrically conductive contact that may be subsequently used for electrically coupling the bridge 404.

FIG. 4H shows a cross section side view of a stage in the manufacturing process where a mold material 406, which may also be referred to as a mold compound or as a mold, is placed around the dies 402, and the bridge 404.

FIG. 4I shows a cross section side view of a stage in the manufacturing process where the mold material 406 is ground down flush with the surface of the copper pillars 414 and/or the bridge 404.

FIG. 4J shows a cross section side view of a stage in the manufacturing process where an interconnect 412, which may be similar to interconnect 112 of FIG. 1, is placed on the copper pillars 414. In embodiments, the interconnect 412 may consist of solder balls, or other solder connections.

FIG. 4K shows a cross section side view of a stage in the manufacturing process where the package shown in FIG. 4J is flipped, the carrier 450 is removed, and a second carrier 464 is applied. In embodiments, the second carrier 464 may be applied over the interconnect 412, and may include grinding tape.

FIG. 4L shows a cross section side view of a stage in the manufacturing process where a groove 432, which may be similar to groove 332 of FIG. 3, is sawn into the mold material 406, between the dies 402, and down toward the bridge 404 to the protector 462. In embodiments, the groove 432 may be made using a half cut and/or a laser cut.

FIG. 4M shows a cross section side view of a stage in the manufacturing process where a fill material 440, which may be similar to fill material 240 of FIG. 2B, may be applied, including into groove 432.

FIG. 4N shows a cross section side view of a stage in the manufacturing process where a top portion of the fill material 440 is ground, leaving fill 441. The second carrier 464 is also removed, exposing the interconnects 412, which may then be coupled with pads 410a of substrate 410, which may be similar to substrate 110 of FIG. 1.

FIG. 4O shows a cross section side view of a stage in the manufacturing process where the package is complete, with interconnect 412 being electrically and physically coupled with substrate 410 at the pads 410a.

FIG. 4P shows a cross section side view of an alternative stage in the manufacturing process, just after the stage in FIG. 4I, where the carrier 450 is removed, the package is flipped, and a second carrier 466 is applied.

FIG. 4Q shows a cross section side view of a stage in the manufacturing process where a groove 434 is sawn into the mold material 406. In embodiments, the groove 434 may be similar to groove 432 of FIG. 4L.

FIG. 4R shows a cross section side view of a stage in the manufacturing process where the groove 434 is filled with a filling material 443.

FIG. 4S shows a cross section side view of a stage in the manufacturing process where the package shown in FIG. 4R is flipped, the second carrier 466 is removed, and a third carrier 468 is applied.

FIG. 4T shows a cross section side view of a stage in the manufacturing process where interconnects 412 are applied to the copper pillars 414. At this point, the manufacturing process may proceed to FIG. 4N.

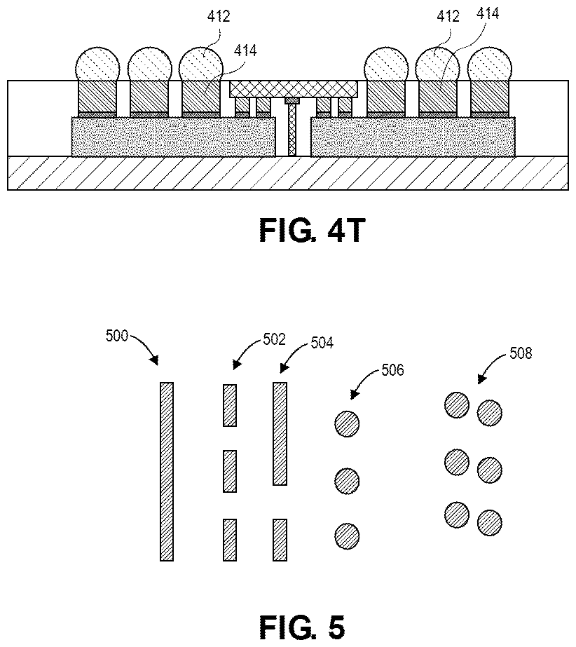

FIG. 5 illustrates top-down views of various patterns of grooves that may be made in a mold material of a package, in accordance with various embodiments. In embodiments the grooves, which may be similar to grooves 230, 232 of FIG. 2A, grooves 320, 332, 334 of FIG. 3, groove 432 of FIG. 4B, may be implemented in a number of different ways. For example, diagram 500 shows grooves implemented in a straight line. Diagram 502 shows grooves implemented in a dashed line. Diagram 504 shows grooves implemented in different sized dashes, in a line. It should be appreciated that any shape, from a top-down perspective, may be used for the grooves in FIG. 5. These shapes may include, but are not limited to, curved lines, serpentine lines, spiral lines, lines that radiate from a location, and the like. In embodiments, the grooves may be referred to as trenches, or may be referred to as lines.

Diagram 506 shows grooves implemented as a series of dotted lines, which may be similar to vias. Diagram 508 shows grooves implemented in multiple lines, for example in side-by-side columns of dotted lines. It should be appreciated that these are a very small sample of the broad range of groove shapes and characteristics that may be used in various embodiments. In addition grooves themselves may be not linear, but may be curved, S shaped, or may have some other complex pattern. In addition, the grooves may have varying widths and/or varying depths. Also, the grooves may be positioned anywhere within a package or within a the mold material of the package, and not necessarily between any particular components, for example between dies, or above a bridge.

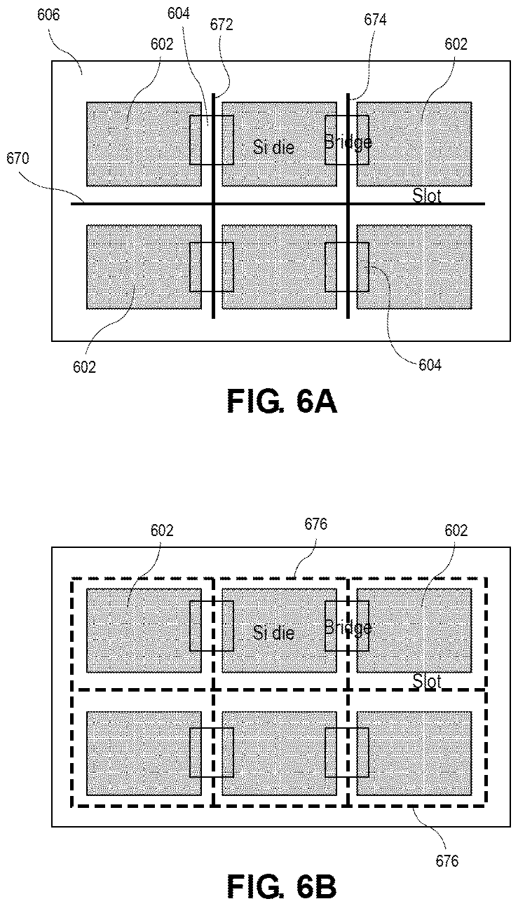

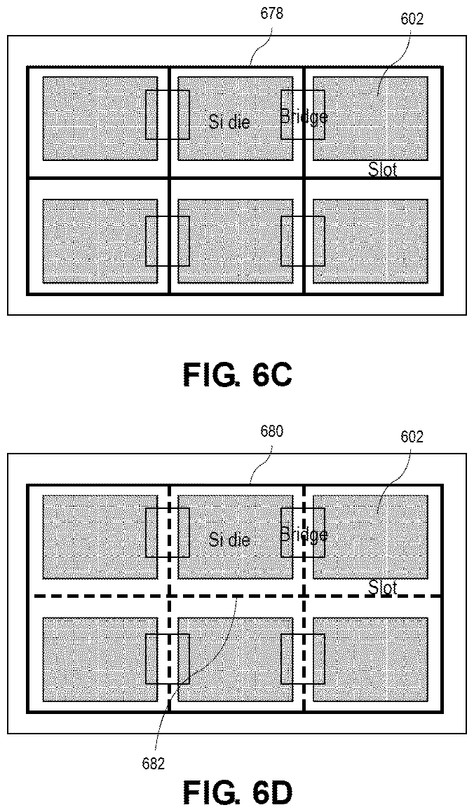

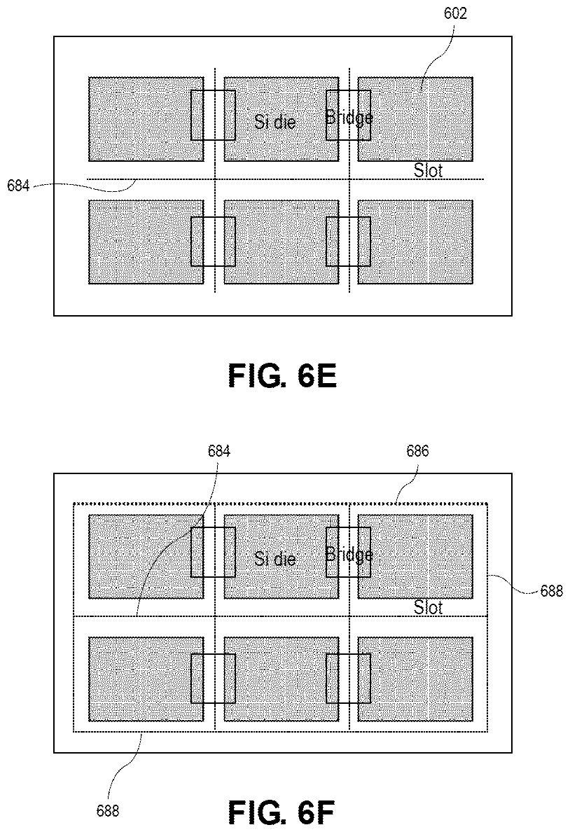

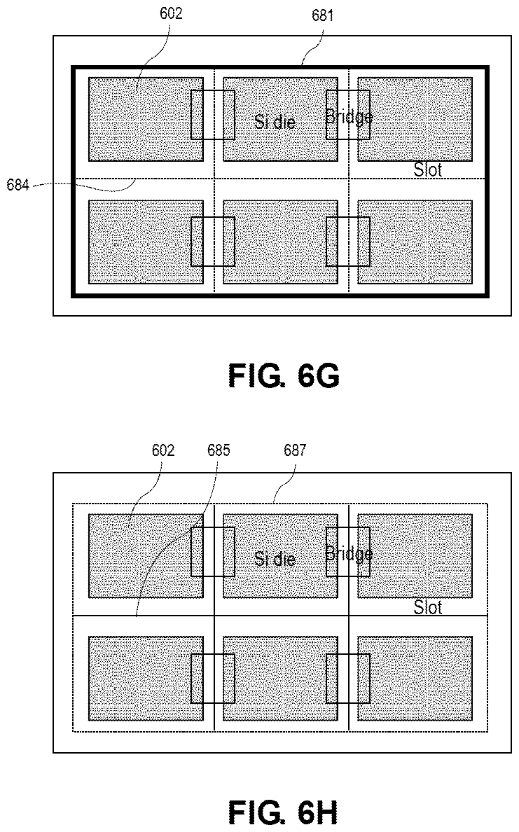

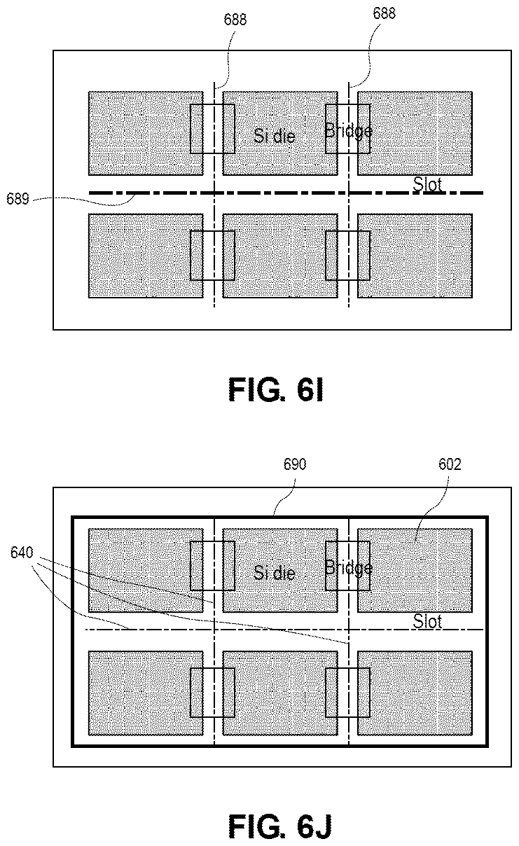

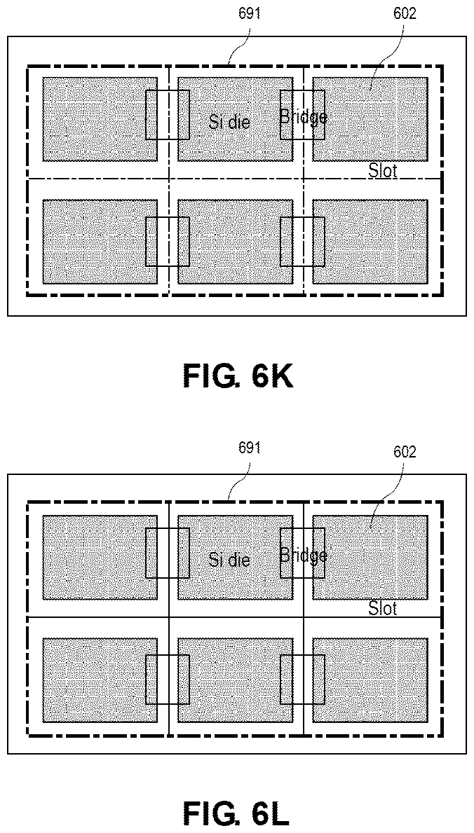

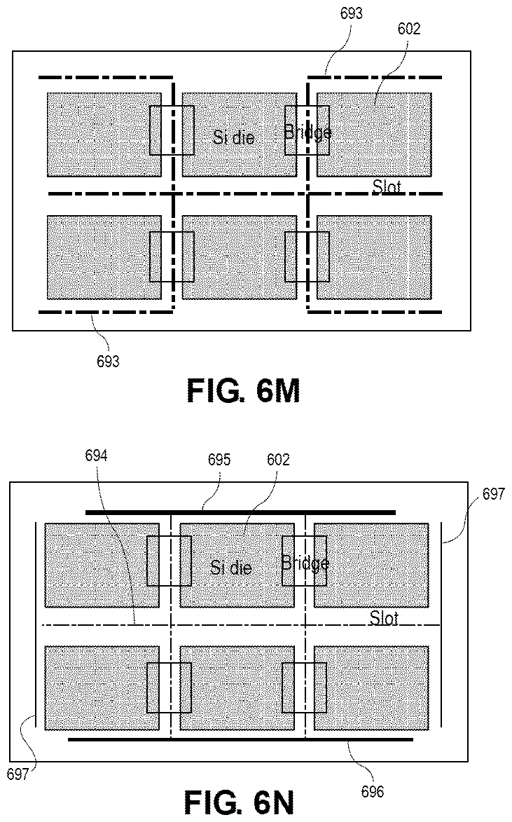

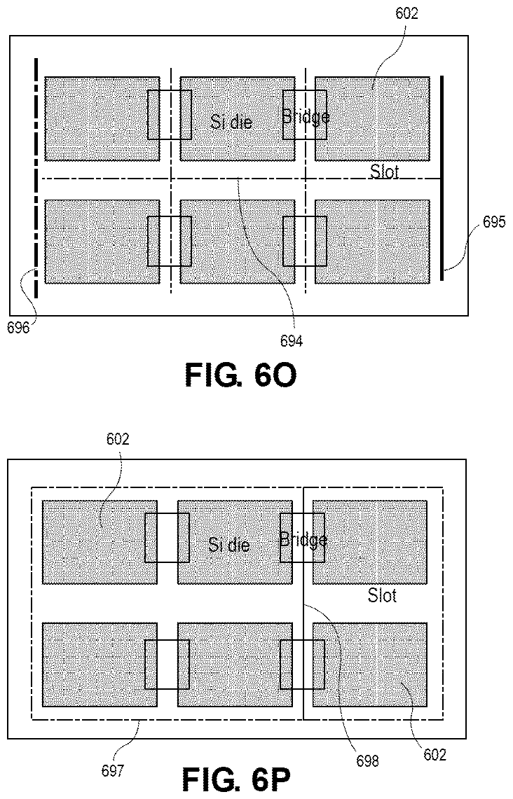

FIGS. 6A-6P illustrate various top-down views of patterns of grooves in mold material of a package, in accordance with various embodiments. These illustrate various non-limiting embodiments of patterns of grooves.

FIG. 6A shows a package that includes a plurality of dies 602, which may be similar to dies 202 of FIG. 2A, or dies 302 of FIG. 3, connected by bridges 604, which may be similar to bridges 204 of FIG. 2A or bridges 304 of FIG. 3, all encapsulated within a mold material 606. As shown, the grooves 670, 672, 674 all appear as solid lines in a top-down view, separate each of the dies 602 from the other and extend over the bridges 604.

FIG. 6B shows a package that is similar to the package of FIG. 6A, with the grooves 676 in a dashed line pattern, that completely surround each of the dies 602.

FIG. 6C shows a package that is similar to the package of FIG. 6B, where the groove 678 is a continuous line that surrounds each of the dies 602.

FIG. 6D shows a package that is similar to the package of FIG. 6C, but with a first groove 680 that is a solid line that surrounds the group of dies 602, with a second groove 682 that is a dashed line that separates each individual dies 602.

FIG. 6E shows a package that is similar to FIG. 6A, however the grooves 684 between the dies 602 are implemented in a dot shape.

FIG. 6F shows a package that is similar to the package of FIG. 6E, where a thicker dotted groove 686 is at one side edge of the package, with a thinner dotted groove 688 around the other three edges of the package, with grooves 684 between the dies 602.

FIG. 6G shows a package that is similar to the package of FIG. 6F, with the groove 684 between the dies 602 implemented in a dot shape, but groove 681 is a thick line that surrounds all of the dies 602.

FIG. 6H shows a package that is similar to the package of FIG. 6G, with the groove 685 between the dies 602 being a solid line, and the groove 687 surrounding all of the dies 602 is a dotted line.

FIG. 6I shows a package that is similar to the package of FIG. 6E, where the grooves 688 are implemented in a dot and dashed pattern, and the groove 689 is implemented in a thicker dot and dashed pattern.

FIG. 6J shows a package that is similar to the package of FIG. 6I, with a thicker solid groove 690 surrounding all of the dies 602, and a dot and dashed pattern 640 separating the dies 602.

FIG. 6K shows a package that is similar to the package of FIG. 6J, however there is a thicker dot and dashed pattern of groove 691 that surrounds all of the dies 602.

FIG. 6L shows a package that is similar to the package of FIG. 6H, where a dot and dashed pattern of groove 691 surrounds all of the dies 602.

FIG. 6M shows a package where a thick dot and dashed pattern of groove 693 surrounds only three sides of each die 602.

FIG. 6N shows a package where a thick solid linear groove 695 is at one edge of the package, a thinner solid linear groove 696 is at the opposite edge of the package, and thinner solid grooves 697 are at either of the other edges of the package, with an internal dot and dashed pattern groove 694 between the dies 602.

FIG. 6O shows a package with an internal dot and dashed pattern groove 694 between the dies 602, with a solid thick groove 695 at one edge of the package, and dot and dashed pattern groove 696 at the opposite edge of the package.

FIG. 6P shows a package with a thin dot and dashed pattern groove 697 surrounding the dies 602, with a solid groove 698 extending from one edge of the dye to another edge of the die.

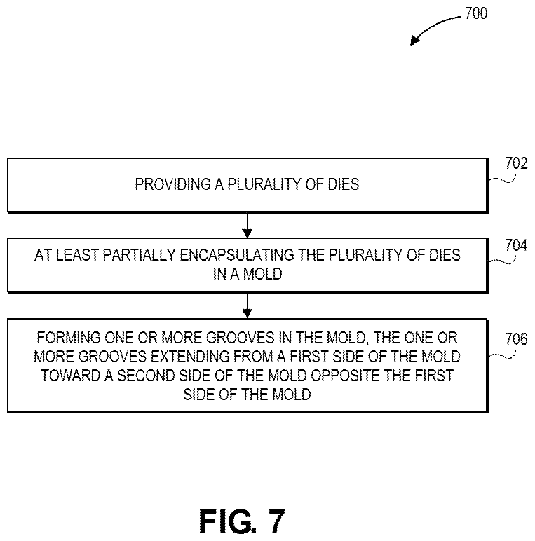

FIG. 7 illustrates an example of a process for creating a package with grooves in a mold material of the package, in accordance with various embodiments. The process 700 may be performed using the apparatus, systems, processes, and/or techniques described herein, and in particular with respect to FIGS. 1-6P

At block 702, the process may include providing a plurality of dies. In embodiments, the plurality of dies may be similar to dies 202 of FIG. 2A, dies 302 of FIG. 3, dies 502 of FIGS. 5B-5T, and/or dies 602 of FIGS. 6A-6P.

At block 704, the process may further include at least partially encapsulating the plurality of dies in a mold material. In embodiments, the mold material may be similar to mold material 206 of FIG. 2A-2B, mold material 306 of FIG. 3, mold material 506 of FIGS. 5H-5T, and/or mold material 606 of FIGS. 6A-6P.

At block 706, the process may further include forming one or more grooves in the mold material, the one or more grooves extending from a first side of the mold material toward a second side of the mold material opposite the first side of the mold material. In embodiments, the grooves may be similar to grooves 230, 232 of FIGS. 2A-2B, grooves 320, 332, 334 of FIG. 3, groove 432 of FIG. 4L, groove 434 of FIG. 4Q, grooves 500, 502, 504, 506, 508 of FIG. 5, and/or grooves 670, 672, 674, 676, 678, 680, 682, 684, 685, 686, 687, 688, 689, 690, 691, 692, 693, 694, 695, 696, 697, 698, of FIGS. 6A-6P.

It should be appreciated that although process 800 refers to a mold material, a substrate, a dielectric, or any other physical feature that may be part of a package may have one or more grooves cut within it to provide flexibility for the package.

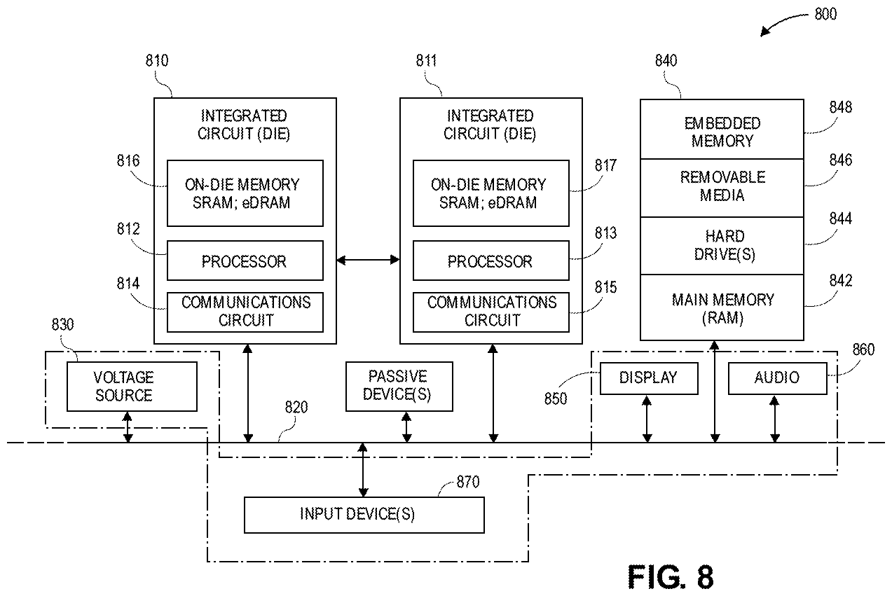

FIG. 8 is a schematic of a computer system 800, in accordance with an embodiment of the present invention. The computer system 800 (also referred to as the electronic system 800) as depicted can embody a grooved package, according to any of the several disclosed embodiments and their equivalents as set forth in this disclosure. The computer system 800 may be a mobile device such as a netbook computer. The computer system 800 may be a mobile device such as a wireless smart phone. The computer system 800 may be a desktop computer. The computer system 800 may be a hand-held reader. The computer system 800 may be a server system. The computer system 800 may be a supercomputer or high-performance computing system.

In an embodiment, the electronic system 800 is a computer system that includes a system bus 820 to electrically couple the various components of the electronic system 800. The system bus 820 is a single bus or any combination of busses according to various embodiments. The electronic system 800 includes a voltage source 830 that provides power to the integrated circuit 810. In some embodiments, the voltage source 830 supplies current to the integrated circuit 810 through the system bus 820.

The integrated circuit 810 is electrically coupled to the system bus 820 and includes any circuit, or combination of circuits according to an embodiment. In an embodiment, the integrated circuit 810 includes a processor 812 that can be of any type. As used herein, the processor 812 may mean any type of circuit such as, but not limited to, a microprocessor, a microcontroller, a graphics processor, a digital signal processor, or another processor. In an embodiment, the processor 812 includes, or is coupled with, a grooved package, as disclosed herein. In an embodiment, SRAM embodiments are found in memory caches of the processor. Other types of circuits that can be included in the integrated circuit 810 are a custom circuit or an application-specific integrated circuit (ASIC), such as a communications circuit 814 for use in wireless devices such as cellular telephones, smart phones, pagers, portable computers, two-way radios, and similar electronic systems, or a communications circuit for servers. In an embodiment, the integrated circuit 810 includes on-die memory 816 such as static random-access memory (SRAM). In an embodiment, the integrated circuit 810 includes embedded on-die memory 816 such as embedded dynamic random-access memory (eDRAM).

In an embodiment, the integrated circuit 810 is complemented with a subsequent integrated circuit 811. Useful embodiments include a dual processor 813 and a dual communications circuit 815 and dual on-die memory 817 such as SRAM. In an embodiment, the dual integrated circuit 810 includes embedded on-die memory 817 such as eDRAM.

In an embodiment, the electronic system 800 also includes an external memory 840 that in turn may include one or more memory elements suitable to the particular application, such as a main memory 842 in the form of RAM, one or more hard drives 844, and/or one or more drives that handle removable media 846, such as diskettes, compact disks (CDs), digital variable disks (DVDs), flash memory drives, and other removable media known in the art. The external memory 840 may also be embedded memory 848 such as the first die in a die stack, according to an embodiment.

In an embodiment, the electronic system 800 also includes a display device 850, an audio output 860. In an embodiment, the electronic system 800 includes an input device such as a controller 870 that may be a keyboard, mouse, trackball, game controller, microphone, voice-recognition device, or any other input device that inputs information into the electronic system 800. In an embodiment, an input device 870 is a camera. In an embodiment, an input device 870 is a digital sound recorder. In an embodiment, an input device 870 is a camera and a digital sound recorder.

As shown herein, the integrated circuit 810 can be implemented in a number of different embodiments, including a package substrate having a grooved package, according to any of the several disclosed embodiments and their equivalents, an electronic system, a computer system, one or more methods of fabricating an integrated circuit, and one or more methods of fabricating an electronic assembly that includes a package substrate having a grooved package, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a grooved package embodiments and their equivalents. A foundation substrate may be included, as represented by the dashed line of FIG. 8. Passive devices may also be included, as is also depicted in FIG. 8.

### EXAMPLES

The following paragraphs describe examples of various embodiments.

Example 1 is a package comprising: a first die and a second die; a mold material surrounding a first die and a second die; and a groove in the mold material, the groove extending from a first side of the mold material toward a second side of the mold material opposite the first side.

Example 2 may include the package of example 1, or of any other example or embodiment described herein, wherein the first die and the second die are in a first plane, and wherein at least a portion of the groove is between the first die and the second die with respect to a second plane that is perpendicular to the first plane.

Example 3 may include the package of example 2, or of any other example or embodiment described herein, wherein the at least a portion of the groove is between the first die in the second die.

Example 4 may include the package of example 2, or of any other example or embodiment described herein, further comprising a component that physically and electrically couples with the first die and with the second die.

Example 5 may include the package of example 4, or of any other example or embodiment described herein, wherein the component is a bridge.

Example 6 may include the package of example 4, or of any other example or embodiment described herein, wherein the at least a portion of the groove extends from the first side of the mold material to a location proximate to a surface of the component.

Example 7 may include the package of example 4, or of any other example or embodiment described herein, wherein the groove is filled with a selected one or more of: a dielectric, a thermal conductor, a thermal insulator, or an electromagnetic insulator.

Example 8 may include the package of example 4, or of any other example or embodiment described herein, wherein the at least a portion of the groove extends from the first side of the mold material to the component, wherein the groove is at least partially filled with an electrically conductive material, wherein the electrically conductive material is electrically coupled with the component.

Example 9 may include the package of example 4, or of any other example or embodiment described herein, wherein the groove extends from a first edge of the mold material to a second edge of the mold material, wherein the first edge of the mold material and the second edge of the mold material are substantially perpendicular to the first side of the mold material.

Example 10 may include the package of example 1, or of any other example or embodiment described herein, wherein the groove may be a selected one or more of: a continuous trench or an intermittent trench.

Example 11 may include the package of example 1, or of any other example or embodiment described herein, wherein the first die and/or the second die are electrically coupled with one or more solder balls at a side of the package.

Example 12 is a package comprising: a plurality of dies; a mold material surrounding the plurality of dies; a plurality of grooves in the mold material, each of the plurality of grooves extending from a first side of the mold material toward a second side of the mold material opposite the first side; and wherein each of the plurality of grooves at least partially separate a first of the plurality of dies from a second of the plurality of dies.

Example 13 may include the package of example 12, or of any other example or embodiment described herein, wherein the plurality of dies are in substantially a same plane.

Example 14 may include the package of example 12, or of any other example or embodiment described herein, further comprising one or more bridges that are electrically and physically coupled with at least a subset of the plurality of dies, wherein the one or more bridges are within the mold material.

Example 15 may include the package of example 14, or of any other example or embodiment described herein, wherein at least some of the plurality of grooves extend from the first side of the mold material to a location proximate to a surface of at least one of the one or more bridges.

Example 16 may include the package of example 14, or of any other example or embodiment described herein, wherein at least some of the plurality of grooves extend from the first side of the mold material to a surface of at least one of the one or more bridges.

Example 17 may include the package of example 16, or of any other example or embodiment described herein, further comprising an electrically conductive material within the at least some of the plurality of grooves, wherein the electrically conductive material electrically couples with the at least one of the one or more bridges.

Example 18 may include the package of example 12, or of any other example or embodiment described herein, wherein at least some of the plurality of grooves are substantially perpendicular to each other.

Example 19 may include the package of example 12, or of any other example or embodiment described herein, wherein the plurality of grooves include a first portion of the plurality of grooves is a continuous trench, and a second portion of the plurality of grooves is an intermittent trench.

Example 20 may include the package of example 12, or of any other example or embodiment described herein, wherein at least some of the plurality of grooves are not linear, with respect to a plane of the first side of the mold material.

Example 21 may include the package of example 12, or of any other example or embodiment described herein, wherein the plurality of grooves are located based upon an arrangement of the plurality of dies within the mold material.

Example 22 is a method comprising: providing a plurality of dies; at least partially encapsulating the plurality of dies in a mold material; and forming one or more grooves in the mold material, the one or more grooves extending from a first side of the mold material toward a second side of the mold material opposite the first side of the mold material.

Example 23 may include the method of example 22, or of any other example or embodiment described herein, further comprising filling the formed one or more grooves with a material.

Example 24 may include the method of example 22, or of any other example or embodiment described herein, wherein after the step of providing a plurality of dies, further comprising physically and electrically coupling one or more bridges to at least some of the plurality of dies; and wherein forming one or more grooves in the mold material further comprises forming one or more grooves in the mold material, wherein at least a portion of the formed one or more grooves is between a first die in a second die of the plurality of dies, and wherein the at least a portion of the formed one or more grooves is above at least one of the one or more bridges.

Example 25 may include the method of example 22, or of any other example or embodiment described herein, wherein forming one or more grooves in the mold material further includes forming one or more grooves in the mold material using a selected one or more of: sawing or laser grooving.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A package comprising:
a first die and a second die;
a mold material surrounding a first die and a second die; and
a groove in the mold material, the groove extending from a first side of the mold material toward a second side of the mold material opposite the first side.

2. The package of claim 1, wherein the first die and the second die are in a first plane, and wherein at least a portion of the groove is between the first die and the second die with respect to a second plane that is perpendicular to the first plane.

3. The package of claim 2, wherein the at least a portion of the groove is between the first die in the second die.

4. The package of claim 2, further comprising a component that physically and electrically couples with the first die and with the second die.

5. The package of claim 4, wherein the component is a bridge.

6. The package of claim 4, wherein the at least a portion of the groove extends from the first side of the mold material to a location proximate to a surface of the component.

7. The package of claim 4, wherein the groove is filled with a selected one or more of: a dielectric, a thermal conductor, a thermal insulator, or an electromagnetic insulator.

8. The package of claim 4, wherein the at least a portion of the groove extends from the first side of the mold material to the component, wherein the groove is at least partially filled with an electrically conductive material, wherein the electrically conductive material is electrically coupled with the component.

9. The package of claim 4, wherein the groove extends from a first edge of the mold material to a second edge of the mold material, wherein the first edge of the mold material and the second edge of the mold material are substantially perpendicular to the first side of the mold material.

10. The package of claim 1, wherein the groove may be a selected one or more of: a continuous trench or an intermittent trench.

11. The package of claim 1, wherein the first die and/or the second die are electrically coupled with one or more solder balls at a side of the package.

12. A package comprising:
a plurality of dies;
a mold material surrounding the plurality of dies;
a plurality of grooves in the mold material, each of the plurality of grooves extending from a first side of the mold material toward a second side of the mold material opposite the first side; and
wherein each of the plurality of grooves at least partially separate a first of the plurality of dies from a second of the plurality of dies.

13. The package of claim 12, wherein the plurality of dies are in substantially a same plane.

14. The package of claim 12, further comprising one or more bridges that are electrically and physically coupled with at least a subset of the plurality of dies, wherein the one or more bridges are within the mold material.

15. The package of claim 14, wherein at least some of the plurality of grooves extend from the first side of the mold material to a location proximate to a surface of at least one of the one or more bridges.

16. The package of claim 14, wherein at least some of the plurality of grooves extend from the first side of the mold material to a surface of at least one of the one or more bridges.

17. The package of claim 16, further comprising an electrically conductive material within the at least some of the plurality of grooves, wherein the electrically conductive material electrically couples with the at least one of the one or more bridges.

18. The package of claim 12, wherein at least some of the plurality of grooves are substantially perpendicular to each other.

19. The package of claim 12, wherein the plurality of grooves include a first portion of the plurality of grooves is a continuous trench, and a second portion of the plurality of grooves is an intermittent trench.

20. The package of claim 12, wherein at least some of the plurality of grooves are not linear, with respect to a plane of the first side of the mold material.

21. The package of claim 12, wherein the plurality of grooves are located based upon an arrangement of the plurality of dies within the mold material.

22. A method comprising:
providing a plurality of dies;
at least partially encapsulating the plurality of dies in a mold material; and
forming one or more grooves in the mold material, the one or more grooves extending from a first side of the mold material toward a second side of the mold material opposite the first side of the mold material.

23. The method of claim 22, further comprising filling the formed one or more grooves with a material.

24. The method of claim 22, wherein after the step of providing a plurality of dies, further comprising physically and electrically coupling one or more bridges to at least some of the plurality of dies; and
wherein forming one or more grooves in the mold material further comprises forming one or more grooves in the mold material, wherein at least a portion of the formed one or more grooves is between a first die in a second die of the plurality of dies, and wherein the at least a portion of the formed one or more grooves is above at least one of the one or more bridges.

25. The method of claim 22, wherein forming one or more grooves in the mold material further includes forming one or more grooves in the mold material using a selected one or more of: sawing or laser grooving.
